(19) United States
(12) Patent Application Publication
(10) Pub. No.: US 2025/0318276 A1
(43) Pub. Date: Oct. 9, 2025

(54) UNIVERSAL GATE PROTECTION DIODE

(71) Applicant: STMicroelectronics International N.V., Geneva (CH)

(72) Inventor: Laurent Lopez, Peynier (FR)

(21) Appl. No.: 19/071,567

(22) Filed: Mar. 5, 2025

(30) Foreign Application Priority Data
Apr. 9, 2024 (FR) FR2403640

(51) Int. Cl. H10D 89/60; H10D 84/85

(52) U.S. Cl. CPC H10D 89/611; H10D 84/859

(57) ABSTRACT

An embodiment metal oxide semiconductor (MOS) device includes an MOS capacitor having a well and a gate disposed a semiconductor substrate of a first doping type; and a gate protection diode disposed the semiconductor substrate. The gate protection diode includes a first region doped with the first doping type and coupled to the gate of the MOS capacitor. The gate protection diode includes a second region distinct from the well of the MOS capacitor and doped with a second doping type different from the first doping type.

### CROSS-REFERENCE TO RELATED APPLICATIONS

This application claims priority to French Application No. 2403640, filed on Apr. 9, 2024, which application is hereby incorporated herein by reference.

### TECHNICAL FIELD

Embodiments and implementations relate to the field of semiconductor components and more particularly to that of gate protection diodes.

### BACKGROUND

The gates are present in metal-oxide semiconductor (MOS) components incorporating an MOS capacity, such as an MOS capacitor or an MOS transistor.

The manufacture of these MOS components and more generally of metal-oxide semiconductor (MOS) circuits involves plasma processes, in particular for the deposition and etching of layers, for example the layers of an integrated circuit interconnection part, located above the substrate and usually referred to by the English acronym “BEOL” for “Back-End Of Line”.

However, these methods can cause damage from plasma charges bombarding the metal lines of the integrated circuit interconnection part. Indeed, when these metal lines are connected to a gate structure of a MOS capacitor, the charges are collected at the gate structure; a high electric field develops through the gate and the substrate is likely to degrade the gate oxide.

It is known to reduce damage from plasma charges by using a gate protection diode, two examples of which are shown in FIG. 1 for NMOS and PMOS transistors. The gate protection diode 10 is integrated into the same substrate 20 as the MOS transistor to be protected 30, in the immediate vicinity thereof, and shares the same N- or P-doped body or well 11. The gate 31 of the MOS transistor is connected to the other side of the diode 12, which therefore has the same P or N doping as the gate.

In this way, between the gate and the substrate, the diode has a lower impedance than the MOS transistor, whatever its polarisation. In this way, the diode, which is passivated, eliminates towards the substrate the charges accumulated at the polarised accumulation gate. On the other hand, the diode becomes blocking when the MOS transistor is reverse polarised (at its gate), which is the case with normal use of a MOSFET transistor (FET for “field-effect transistor”).

However, such a gate protection diode is not satisfactory for certain applications, such as the simple use of an MOS capacitor which is symmetrical in nature, but also a “power switch” type use of a MOSFET transistor, where the gate of the MOS transistor can be used according to inversion and accumulation polarisation.

In the case of accumulation polarisation, the gate protection diode is in forward polarisation (and therefore conducting) and a leakage current flows through the diode, leading to unnecessary current consumption and, in some cases, problems with the application's functionality.

There is therefore a need to provide an improved gate protection diode that allows the gate of the MOS component to be used in both polarisations, without overconsuming electricity.

### SUMMARY

According to one aspect, a metal oxide semiconductor (MOS) device is provided in a semiconductor substrate of a first doping type, the MOS device comprising: an MOS capacitor having a well and a gate, and a gate protection diode comprising a first region doped with the first doping type and adapted to be connected to the gate of the MOS capacitor, the gate protection diode comprising a second region distinct from the well of the MOS capacitor and doped with a second doping type different from the first doping type. This second region therefore forms the well of the gate protection diode.

“Distinct” is defined to mean that the regions concerned are separated by an undoped region (e.g. an STI shallow trench isolation) or by a differently doped region.

By dissociating the wells of the MOS capacitor to be protected and the gate protection diode, the latter has two P-N junctions—and therefore two diodes in series—in opposite directions or head to tail in the electrical diagram: that of the diode, and the opposite junction between the second region and the substrate. Due to their reverse bias (one of the two diodes in series is conducting, the other blocking), only a small leakage current can flow, limited by the blocking diode, whatever the polarisation applied to the gate. This low current allows the elimination of plasma charges accumulated during the manufacture of the MOS circuit, while avoiding a high leakage current when using the MOS component in either of the gate polarisations. The MOS device designed in this way is also protected.

The two P-N junctions in opposite directions free the device from the constraints of the relative polarisations of the gate protection diode and the MOS capacitor. It is therefore possible to use the same type of gate protection diode to protect MOS components, regardless of their gate polarisation, unlike known protection diodes. Such a gate protection diode is therefore “universal” in nature. Also, in an advantageous embodiment, the well of the MOS capacitor is doped with the first type of doping, opposite that of the well of the gate protection diode, as is customary.

Furthermore, it is also possible to protect several MOS components simultaneously with the same universal gate protection diode, the gates of which are at the same potential, regardless of the applied polarisation.

Furthermore, as no new junction is created-only the wells of the MOS capacitor and the gate protection diode having to be separated-the complexity of the design of this gate protection diode is not altered.

A metal-oxide semiconductor (MOS) integrated circuit comprising an MOS device as defined above is also proposed.

According to a second aspect, a method is proposed for manufacturing a protected metal-oxide semiconductor device (MOS), the method comprising: forming, in a semiconductor substrate of a first doping type, an MOS capacitor having a well and a gate, and forming, in the semiconductor substrate, a gate protection diode comprising a first region doped with the first doping type and adapted to be connected to the gate of the MOS capacitor, and a second region distinct from the well of the MOS capacitor and doped with a second doping type different from the first doping type.

The method has the same advantages as those of the aforementioned device.

Optional features of embodiments are defined in the attached claims. Some of these features are explained below with reference to a device, which can be translated into features of the method.

In one embodiment, the second region of the gate protection diode is floating, i.e. it is not polarised either to the supply voltage VDD or to ground. This arrangement prevents short-circuiting of the second junction, and consequently prevents any leakage current.

In another embodiment, the MOS device also comprises a first doped barrier of the first doping type between the gate protection diode and the MOS capacitor, and a second doped barrier of the second doping type between the first barrier and the MOS capacitor. In this way, the gate protection diode and the MOS capacitor are spaced apart, helping to reduce the risk of forming a parasitic thyristor (or “latchup”) due to the PNPN structure formed by the protection diode and the well of the MOS capacitor.

In a particular feature, the first and second barriers form rings around the gate protection diode. Omnidirectional protection against the risk of a parasitic path is thus achieved, facilitating the integration design of the universal gate protection diode in an integrated circuit.

The first and second barriers are preferably polarised, one to earth and the other to a supply voltage. The second barrier thus imposes a stable polarised region in the substrate, between the gate protection diode and the MOS capacitor. This stable intermediate polarisation actively contributes to reducing the risk of forming a PNPN parasitic thyristor.

According to one particular feature, the first barrier is polarised like the substrate, i.e. at the same potential. According to a corresponding feature, the second barrier is polarised at the other potential by the ground and a supply voltage.

As illustrated below, the first and second barriers may be separated by an undoped region, typically an isolated STI trench.

In one embodiment representing a preferred application, the MOS capacitor forms part of a MOS field effect transistor (MOSFET). This is the MOS capacitor formed by the gate of the transistor and its substrate, creating the conduction channel of the transistor.

In one embodiment, transistors of different types in the same circuit can be protected by universal gate protection diodes. Also, in the integrated circuit referred to above, the MOS capacitor of the first MOS device may form part of an NMOS transistor, and the circuit may comprise a second MOS device as defined above, sharing the same substrate as the first MOS device, the MOS capacitor of the second MOS device forming part of a PMOS transistor.

In a particular embodiment, each of the first and second MOS devices comprises a first ring around the corresponding gate protection diode and doped with the first type of doping, and comprises a second ring around the first ring and doped with the second type of doping.

### BRIEF DESCRIPTION OF THE DRAWINGS

Other advantages and features of the invention will become apparent on reading the detailed description of non-limiting embodiments and implementations, and from the accompanying drawings, wherein:

FIG. 1 illustrates a conventional gate protection diode;

FIG. 2 illustrates, in cross-section, a semiconductor device formed by an N-type transistor (NMOS) protected by a universal gate protection diode in accordance with an embodiment;

FIG. 3 illustrates, in cross-section, a semiconductor device formed by a P-type transistor (PMOS) protected by the same universal gate protection diode in accordance with an embodiment;

FIG. 4 illustrates the resulting electrical diagram of two diodes in series in accordance with an embodiment;

FIG. 5 illustrates the resulting electrical diagram, still with two diodes in series which are head-to-tail, but in reverse order in accordance with an embodiment;

FIG. 6 illustrates, using a flow chart, steps for manufacturing a semiconductor device in accordance with an embodiment;

FIG. 7 illustrates, in cross-section, a semiconductor device according to various embodiments;

FIG. 8 schematically illustrate implementations and embodiments of the invention.

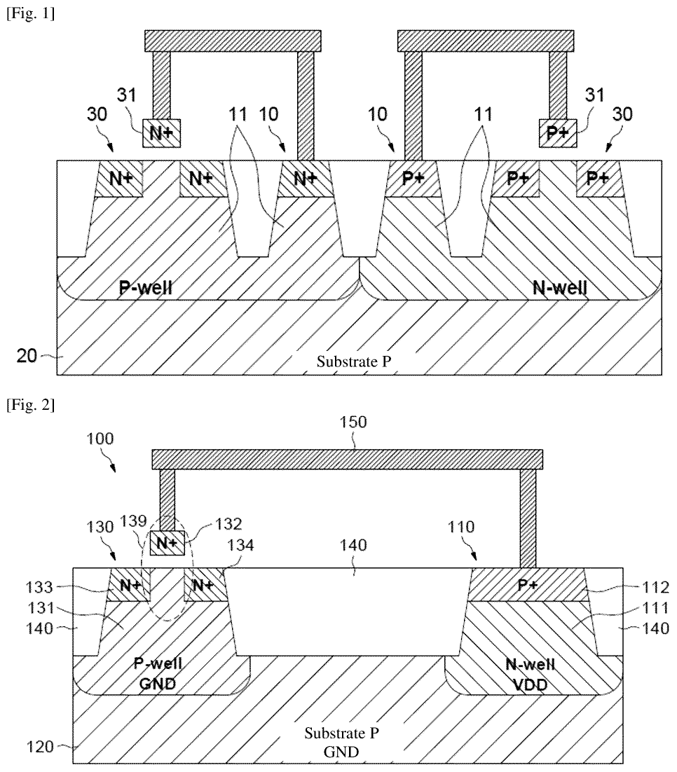

For the purposes of clarity, the same elements are denoted by the same reference signs in the various figures. Furthermore, the various figures are not drawn to scale, as is usual in the representation of integrated circuits.

### DETAILED DESCRIPTION OF ILLUSTRATIVE EMBODIMENTS

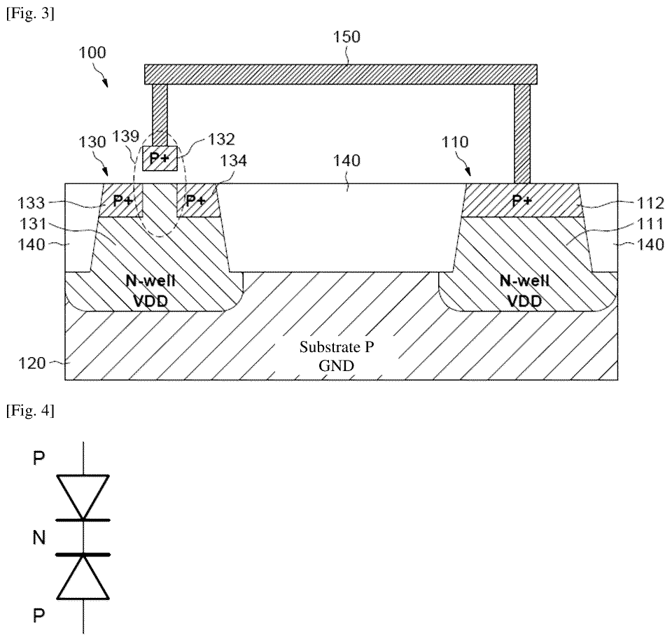

FIG. 2 illustrates, in cross-section, a semiconductor device 100 formed by an N-type transistor (NMOS) 130 protected by a universal gate protection diode 110. FIG. 3 illustrates, in cross-section, a semiconductor device 100 formed by a P-type transistor (PMOS) 130 protected by the same universal gate protection diode 110.

These devices may each form part of an integrated circuit not shown here for reasons of clarity, or may even form part of the same integrated circuit.

Although the devices illustrated show transistors protected by a gate protection diode, any other MOS component with a MOS capacitor between a gate and a body or “well” can be used with the universal gate protection diode described below. This is particularly the case for a MOS capacitor whose diffusion area (carrying the gate) can be of either the same or opposite doping type to its well, which is not the case for an MOS transistor which requires opposite doping types between the gate and the well.

Conventionally, in a semiconductor substrate 120, for example a lightly doped silicon substrate, isolation trenches 140 surround active regions where a transistor 130 and a universal gate protection diode 110 are formed. The isolation trenches 140 are for example narrow and shallow trenches, for example filled with silicon oxide, commonly referred to by the acronym STI (shallow trench isolation).

To form the transistor 130, an active area is doped in a first region according to one type of doping (P for an NMOS transistor and N for a PMOS transistor) to form the well 131 of the transistor, this first region 131 is covered with a gate insulator (not shown, typically silicon dioxide SiO₂) and a metal or polycrystalline silicon gate 132 doped with the other doping type (N for an NMOS transistor and P for a PMOS transistor). The gate 132 and the well 131 therefore have opposite doping. The gate insulator well structure thus forms an MOS capacitor, denoted 139.

Second and third regions of the active area not covered by the gate 132 are doped with the other doping type (N for an NMOS transistor and P for a PMOS transistor) to form the source 133 and drain 134 of the transistor 130.

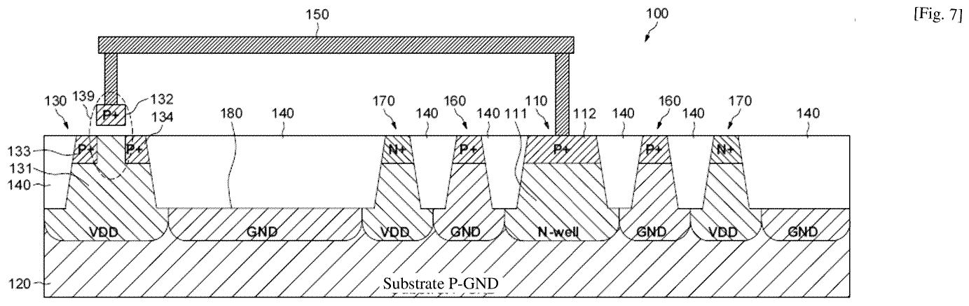

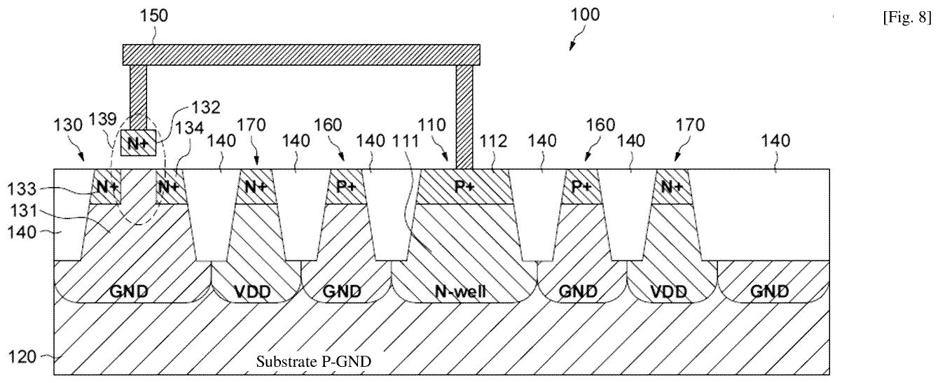

The universal gate protection diode 110 can be formed in the active area adjacent to that of the transistor 130 to be protected, or, as illustrated for example in FIG. 7 or FIG. 8, in a more distant active area. It has a first doped region 112 at the surface of the active area and a second region 111 of opposite doping at the depth of the active area, so as to form a PN junction.

To form the universal gate protection diode 110, the active zone is doped in depth in the second region according to the doping type opposite to that of the substrate 130, to form the body or well 111 of the diode 110. In the figures, the substrate 130 is P-doped. Also, the body 111 of the diode 110 is N-doped.

The doping is carried out so that the well 111 of the diode 110 is distinct from the well 131 of the transistor 130. This physical separation of the areas may result in particular from the spacing between the respective active areas, due to the isolation trench or trenches 140.

In the figures, the most superficial portions of the wells 111, 131 are separated by at least one isolation trench 140, whereas the deepest portions of the wells 111, 131 are simply separated by at least part of the substrate 120. In one embodiment, the entire depths of wells 111, 131 are separated by at least one isolation trench 140.

The active area is also surface doped in the first region with the same type of doping as that of the substrate 130, to form the diffusion area 112 of the diode 110. In the Figures, the diffusion area 112 of the diode 110 is P-doped, like the substrate 120.

The gate 132 of the transistor 130 is electrically connected to the diffusion area 112 of the diode 110. The figures illustrate a metal line 150 which typically has the form of a metal track in any of the layers of a BEOL integrated circuit interconnect portion, located above the substrate.

In the proposed gate protection diode structure 110, the diffusion area 112—well 111 (here PN) junction defines a junction opposite to the well 111—substrate 120 (here NP) junction. As shown in FIG. 4, the resulting electrical diagram is that of two diodes in series which are head-to-tail.

The well 111 is set at a floating potential so as not to create a leakage current. This is made possible by the physical separation of well 111 and well 131 (which will be polarised during the operation of the transistor 130). The gate protection diode 110 is said to be floating.

Thus, a gate discharge current, even a small one (in the order of a few hundred nA or a few μA), can be established between the gate 132 and the substrate 120 via the two junctions of the gate protection diode 110, so as to eliminate the plasma charges accumulated at the gate 132 towards the substrate 120. Typically, the substrate 120 is polarised via an electrical contact on its underside (not illustrated). Typically, the P-type substrate 120 is connected to ground GND. The substrate 120 is also polarised to ground GND by the top surface by the various P-type well connections, which are themselves polarised to GND.

In operation, the regions of the transistor 130 are polarised, typically the source 133 and the P-type well 131 (FIG. 2) are connected to ground GND (NMOS in FIG. 2) or are polarised to a supply voltage VDD (PMOS in FIG. 3), while the drain 134 is polarised in the opposite way, to the supply voltage VDD (NMOS in FIG. 2) or to ground GND (PMOS in FIG. 3).

When the gate 131 of transistor 130 is polarised, regardless of the polarisation, accumulation or inversion, one of the two diodes in FIG. 4 becomes blocking. A very small current therefore leaks through the gate protection diode 110.

This is why the same gate protection diode 110 can be used for NMOS and PMOS transistors (or, more generally, capacitors), as shown in FIG. 2 and FIG. 3.

While these figures illustrate a P-type 120 substrate, similar considerations can be made in the case of an N-type 120 substrate, which is usually polarised to the supply voltage VDD via an electrical contact on its underside (not shown). The only constraint is that of producing an NPN 110 diode structure instead of the PNP structure shown in these figures. To achieve this, the doping of the diffusion area 112 and the well 111 of diode 110 are reversed.

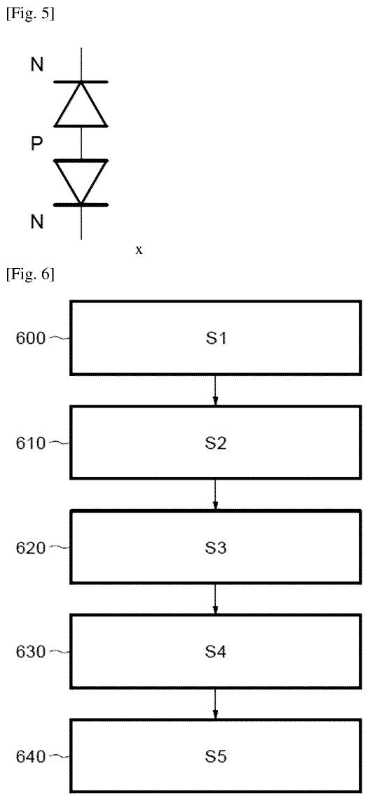

FIG. 5 illustrates the resulting electrical diagram, still with two diodes in series which are head-to-tail, but in reverse order.

FIG. 6 illustrates, using a flow chart, steps for manufacturing a semiconductor device 100.

The process begins in step S1, referred to as step 600, by obtaining a substrate 120 with a main doping of the DP type—either N or P. The reverse doping is referred to as DI—either P or N respectively.

In step S2, referred to as 610, isolation trenches 140 are formed in the substrate 120, creating active zones between each pair of trenches. For example, a pattern of trenches is etched into the substrate 120, in which one or more dielectric materials (such as silicon dioxide SiO₂) are deposited. Excess dielectric material can be removed using appropriate techniques, such as chemical-mechanical planarisation.

An MOS transistor 130 or any MOS component with a MOS capacitor 139 (NMOS or PMOS) is formed in one of the active areas, in step S3 referenced as 620. To achieve this, the well 131 and the source 133 and drain 134 can be formed by ion implantation. The gate insulator and gate 132 are then successively deposited on the upper surface of the well 131 using conventional techniques. Conventional source, drain and substrate electrodes are also created to enable their polarisation.

The gate protection diode 110 is formed in another of the active areas, in step S4 referenced as 630.

Again, an ion implantation technique can be used to form the well 111 at depth and the diffusion area 112 at the surface. In the universal gate protection diode 110, the well 111 is DI doped while the diffusion area 112 is DP doped. In addition, well 111 is formed separate from well 131 of the transistor 130 of the other active area.

A surface electrode in contact with the diffusion area 112 can also be deposited.

Of course, depending on the techniques used to form transistor 130, diode 110 and trenches 140, the order of steps 610-630 may be different.

Step S5 referred to as 640 then consists of electrically connecting the gate protection diode 110 to the transistor 130 to be protected, typically by connecting the gate 131 to the electrode of the diffusion area 112.

Since the purpose of the gate protection diode 110 is to discharge the gate 131 during the plasma processes used to form the integrated circuit interconnection part BEOL, the electrical connection between the gate 131 and the diffusion area 121 is preferably formed in the first metal layer (or one of the very first layers) of the integrated circuit interconnection part.

These steps in FIG. 6 may form part of a more general process for manufacturing a semiconductor integrated circuit.

The same universal gate protection diode 110 can thus be electrically connected (via its diffusion area 112) to two or more MOS components of an integrated circuit, each equipped with a MOS capacitor 139, as long as their gates are polarised at the same potential. These components may also be of different types (PMOS or NMOS).

FIG. 7 illustrates, in cross-section, a semiconductor device 100 according to various embodiments.

In these embodiments, semiconductor barriers are arranged between the gate protection diode 110 and the MOS component 130 to be protected, in this case a PMOS transistor. In the example shown in FIG. 7, the configuration shown in FIG. 3 is repeated.

A first barrier 160 doped like the substrate 120 (P in the example) is arranged in the substrate 120 between the gate protection diode 110 and the MOS capacitor 139, and a second barrier 170 with reverse doping (N in the example) is arranged in the substrate 120 between the first barrier 160 and the MOS capacitor 139.

These barriers 160, 170 have a depth similar to that of the gate protection diode 110 and the MOS component 130, and have a width in the order of um (micrometres). In the figure, they are separated by an isolation trench 140. Also, these barriers 160, 170 can be formed by ion implantation in two active areas delimited by isolation trenches 140 formed in step 610.

Again in the example shown in the figure, the first barrier 160 is positioned in the active area immediately adjacent to the gate protection diode, and the second barrier 170 is positioned in the next active area. Of course, other configurations are possible in which a greater number of isolation trenches 140 separate the gate protection diode 110, the first barrier 160 and the second barrier 170.

As illustrated in the figure by the double references 160 and 170 on either side of the gate protection diode 110, the first and second barriers may each be configured to form a closed figure around the gate protection diode 110. Preferably, the first and second barriers form rings (viewed from above) around the gate protection diode. Other shapes than rings, for example rectangles or squares (in plan view), may be used.

In operation, the first barrier 160 is polarised like the substrate, to ground in the example shown, while the second barrier 170 is oppositely polarised, to the supply voltage VDD in the example shown, so as to provide a stable polarised region between the diode 110 and the MOS component 130.

A spacer region 180 doped like the substrate and polarised like the latter is also formed between the second barrier 170 and the MOS component 130 when the well 131 of the latter is doped like the second barrier 170, as is the case in the Figure. This spacer region 180 may be formed under an isolation trench 140 separating the second barrier 170 and the MOS component 130 (as in the figure) or may be formed as an additional barrier in the active area between two isolation trenches 140 separating the second barrier 170 and the MOS component 130.

The embodiments described in relation to FIG. 7 also apply to the configuration of FIG. 2 where an NMOS transistor 130 is used instead of a PMOS transistor. In this case, the well 131 is not doped like the second barrier 170; the spacer region 180 can be omitted and the MOS component 130 can be placed immediately adjacent to the second barrier 170 (via an isolation trench 140), i.e. their wells can touch. This configuration is illustrated in FIG. 8.

In the event that a spacing is still desired, a spacer region 180 can be maintained which then comprises one or more pairs of successive reverse doped sub-regions, in order to maintain alternate doping from the well 111 of the gate protection diode 110 to the well 131 of the NMOS transistor 130.

The various embodiments presented in connection with the above Figures also apply to configurations that use an N-type substrate instead of a P-type substrate. In this case, an NPN diode 110 structure is used instead of the PNP structure. In addition, the first barrier 160 (FIG. 7 or FIG. 8) is then of type N, typically connected to the supply voltage whereas the second barrier 170 is of type P, typically connected to ground.

What is claimed is:

1. A metal oxide semiconductor (MOS) device comprising:
an MOS capacitor having a well and a gate disposed a semiconductor substrate of a first doping type; and
a gate protection diode disposed the semiconductor substrate, the gate protection diode comprising a first region doped with the first doping type and coupled to the gate of the MOS capacitor, the gate protection diode comprising a second region distinct from the well of the MOS capacitor and doped with a second doping type different from the first doping type.

2. The device according to claim 1, wherein the second region of the gate protection diode is floating.

3. The device according to claim 1, further comprising:
a first barrier doped with the first doping type between the gate protection diode and the MOS capacitor; and
a second barrier doped with the second doping type between the first barrier and the MOS capacitor.

4. The device according to claim 3, wherein the first and second barriers form rings around the gate protection diode.

5. The device according to claim 3, wherein the first barrier and substrate are coupled to a first potential node, and the second barrier is coupled to a second potential node, the first potential node being either a ground node or a supply voltage node and the second potential node being the other of the ground node or the supply voltage node.

6. The device according to claim 3, wherein the first barrier and the substrate are coupled to a ground node or a supply voltage node, and the second barrier is coupled to the other of either the ground node or the supply voltage node.

7. The device according to claim 1, wherein the well of the MOS capacitor is doped with the first doping type.

8. The device according to claim 1, wherein the MOS capacitor forms part of a MOS field effect transistor.

9. A metal-oxide semiconductor (MOS) integrated circuit comprising the MOS field effect transistor according to claim 8.

10. A circuit comprising:
an NMOS transistor having a well and a gate disposed in a semiconductor substrate of a first doping type;
a first gate protection diode disposed the semiconductor substrate, the first gate protection diode comprising a first region doped with the first doping type and coupled to the gate of the NMOS transistor, the first gate protection diode comprising a second region distinct from the well of the NMOS transistor and doped with a second doping type different from the first doping type;
a PMOS transistor having a well and a gate disposed in the semiconductor substrate of the first doping type; and
a second gate protection diode disposed the semiconductor substrate, the second gate protection diode comprising a third region doped with the first doping type and coupled to the gate of the PMOS transistor, the second gate protection diode comprising a fourth region distinct from the well of the PMOS transistor and doped with the second doping type.

11. The circuit according to claim 10, wherein each of the NMOS and PMOS transistors comprises a first ring around the corresponding first or second gate protection diode and doped with the first doping type, and comprises a second ring around the first ring and doped with the second doping type.

12. The circuit according to claim 11, wherein the first and second rings are polarised, one of the first and second rings being coupled to a ground node, the other of the first and second rings coupled to a supply voltage node.

13. The circuit according to claim 11, wherein the first ring and substrate are coupled to a first potential node, and the second ring is coupled to a second potential node, the first potential node being either a ground node or a supply voltage node and the second potential node being the other of the ground node or the supply voltage node.

14. A method of manufacturing a protected metal oxide semiconductor (MOS) device, the method comprising:
forming, in a semiconductor substrate of a first doping type, a MOS capacitor having a well and a gate; and
forming, in the semiconductor substrate, a gate protection diode comprising a first region doped with the first doping type and coupled to the gate of the MOS capacitor, and a second region distinct from the well of the MOS capacitor and doped with a second doping type different from the first doping type.

15. The method according to claim 14, further comprising:
a first barrier doped with the first doping type between the gate protection diode and the MOS capacitor; and
a second barrier doped with the second doping type between the first barrier and the MOS capacitor.

16. The method according to claim 15, wherein the first and second barriers form rings around the gate protection diode.

17. The method according to claim 15, wherein the first and second barriers are polarised, one of the first and second barriers being coupled to a ground node, the other of the first and second barriers coupled to a supply voltage node.

18. The method according to claim 15, wherein the first barrier and substrate are coupled to a first potential node, and the second barrier is coupled to a second potential node, the first potential node being either a ground node or a supply voltage node and the second potential node being the other of the ground node or the supply voltage node.

19. The method according to claim 14, wherein the well of the MOS capacitor is doped with the first doping type.

20. The method according to claim 14, wherein the MOS capacitor forms part of a MOS field effect transistor.
